(19) United States
(12) Patent Application Publication
(10) Pub. No.: US 2007/0234143 A1
(43) Pub. Date: Oct. 4, 2007

(54) SEMICONDUCTOR MEMORY DEVICES AND METHODS OF TESTING FOR FAILED BITS OF SEMICONDUCTOR MEMORY DEVICES

(75) Inventor: Hyung-Min Kim, Gyeonggi-do (KR)

Correspondence Address: MYERS BIGEL SIBLEY & SAJOVEC, PO BOX 37428, RALEIGH, NC, 27627, US

(73) Assignee: SAMSUNG ELECTRONICS CO., LTD.

(21) Appl. No.: 11/688,417

(22) Filed: Mar. 20, 2007

Related U.S. Application Data
(63) Continuation-in-part of application No. 11/526,321, filed on Sep. 25, 2006.

(30) Foreign Application Priority Data
Jan. 11, 2007 (KR) 2007-03449
Jan. 25, 2006 (KR) 2006-07903

(51) Int. Cl. G11C 29/00

(52) U.S. Cl. 714/718

(57) ABSTRACT

A semiconductor memory device includes a flash memory including a plurality of M-byte memory pages, and a buffer memory that includes a first M-byte buffer and a second M-byte buffer and that is configured to receive expected data used to test for failed bits in the flash memory. The semiconductor memory device further includes a fail-bit control unit configured to receive the expected data from the buffer memory, configured to receive the read data from the flash memory, and configured to calculate a failed bit number and a failed bit position in response to a mis-match between the expected data and the read data.

### CROSS-REFERENCE TO RELATED APPLICATIONS

This U.S. non-provisional patent application claims priority under 35 U.S.C § 119 to Korean Patent Application No. 2007-03449 filed on Jan. 11, 2007, the disclosure of which is hereby incorporated by reference. This application is a continuation-in-part of U.S. application Ser. No. 11/526,321, filed on Sep. 25, 2006, the disclosure of which is hereby incorporated by reference.

### FIELD OF THE INVENTION

The present invention relates to semiconductor devices and, more particularly, to semiconductor memory devices and methods of testing semiconductor memory devices.

### BACKGROUND

Semiconductor memory devices can store data and output the stored data on command. Semiconductor memory devices may be roughly categorized into random access memory (RAM) and read only memory (ROM) devices. A RAM device is typically a volatile memory device that loses its stored data at power-off, although some types of RAM devices are non-volatile. Examples of RAM devices include dynamic RAM, static RAM, and the like. The ROM device is a non-volatile memory device that can retain its stored data even at power-off. Examples of ROM devices include programmable ROM (PROM), erasable PROM (EPROM), electrically erasable PROM (EEPROM), flash memory, and the like. Flash memories can be further classified into NAND-type flash memory and NOR-type flash memory depending on the kinds of logic gates used to implement the memory.

In general, a NAND flash memory may include a cell array, which includes a plurality of memory blocks. Each of the memory blocks may include a plurality of pages. A memory block is typically used as the basic unit for an erase operation, and a page is typically used as the basic unit for a read/write operation.

NAND flash memory devices have been successfully utilized in mobile communication terminals, portable media players, digital cameras, portable storage devices, and the like. In order to use a NAND flash memory device as a storage medium, it may be desirable to secure the integrity of data stored in the NAND flash memory device. However, a NAND flash memory can experience bit failures due to its physical characteristics. Thus, some NAND flash memory devices are configured to be able to detect and/or correct bits that have failed (i.e., “failed bits”). In order to detect/correct failed bits, an error correction code (ECC) circuit may be provided in the NAND flash memory device.

An ECC algorithm may be loaded onto the ECC circuit of the NAND flash memory. This may enable the NAND flash memory device to correct failed bits that may be generated during a read/write operation. Accordingly, it is possible to improve the reliability of a NAND flash memory through the use of error detection/correction circuitry.

In general, a number of packaged memory devices may be tested simultaneously to reduce the time required for testing. Since a test apparatus configured to simultaneously test packaged memory devices may have an error capture RAM that has a limited memory capacity, a compressed and/or summarized test result may be stored in the error capture RAM. According to this test scheme, although a memory block of a packaged memory device may have only one failed bit, the memory block will be considered to be a bad block. In this case, it may not be possible to detect the number of failed bits (i.e. a “failed bit number”) of a memory block that has been determined to be a bad block.

A software technique for individually counting failed bits at a test stage may be used to determine the number of failed bits. For example, it is possible to precisely measure a failed bit number for each memory device by storing test results corresponding to all memory cells in an error capture RAM. However, since the storage capacity of the error capture RAM may be limited, the number of memory devices to be tested at the same time may also be limited. This means that the time required to perform the test may be increased.

In methods of counting failed bits in a conventional NAND flash memory, a failed bit number can be detected by inputting expected data through input/output terminals and comparing the expected data with data read from a page of the flash memory. Such a method of generating a failed bit count is disclosed in U.S. patent publication No. 2002-0069381.

In a conventional method of counting failed bits, it may be possible to detect both the existence of a failed bit and the number of failed bits. However, it may not be possible to detect the position of the failed bits (i.e. a “failed bit position”) in the memory. In order to correct failed bits, the position of the failed bits must be determined by a tester. Further, since the sample data from a tester is input in predetermined units (e.g., byte or word units), a long time may be required to test failed bits.

### SUMMARY

A semiconductor memory device according to some embodiments of the invention includes a flash memory including a plurality of M-byte memory pages, and a buffer memory that includes a first M-byte buffer and a second M-byte buffer and that is configured to receive expected data used to test for failed bits in the flash memory. The semiconductor memory device further includes a fail-bit control unit configured to receive the expected data from the buffer memory, configured to receive the read data from the flash memory, and configured to calculate a failed bit number and a failed bit position in response to a mis-match between the expected data and the read data.

The semiconductor memory device may further include an M-byte page buffer configured to receive read data from the flash memory, the fail-bit control unit is configured to receive read data from the page buffer.

The expected data may correspond to a page of the flash memory, and the buffer memory may be further configured to receive the expected data in a single programming operation.

The buffer memory may be configured to store expected data in the first buffer while the fail-bit control unit reads expected data from the second buffer.

The fail-bit control unit may include a failed bit count unit configured to calculate the failed bit number in response to the expected data and the read data, and a failed bit position unit configured to calculate the failed bit position in response to the expected data and the read data.

The failed bit count unit may include a data comparator configured to compare the expected data with the read data, and a failed bit counter configured to calculate the failed bit number from a comparison result of the data comparator.

The failed bit position unit may include an expected data parity generator configured to generate an expected data parity value from the expected data, a read data parity generator configured to generate a read data parity value from the read data, and a failed bit position generator configured to calculate the failed bit position from the expected data parity value and the read data parity value.

The semiconductor memory device may further include a failed bit register configured to store the failed bit number and the failed bit position.

Some embodiments of the invention provide a memory system including a semiconductor memory device that includes a flash memory including a plurality of M-byte memory pages, a buffer memory that includes a first M-byte buffer and a second M-byte buffer and that is configured to receive expected data used to test for failed bits in the flash memory, the buffer memory may, and a fail-bit control unit configured to receive the expected data from the buffer memory, configured to receive the read data from the flash memory, and configured to calculate a failed bit number and a failed bit position in response to the expected data and the read data. The memory system further includes a control unit configured to control a testing operation of the semiconductor memory device and a testing unit configured to store expected data in the buffer memory and configured to notify the control unit of a memory page of the flash memory to be tested.

The testing unit may be configured to store first expected data in the first buffer, and to store second expected data in the second buffer while the fail-bit control unit reads the first expected data from the first buffer,

Some embodiments of the invention provide methods of testing for failed bits in a semiconductor memory device including a flash memory and a buffer memory including first and second buffers. The methods include loading expected data into the first buffer, programming the expected data into the flash memory, reading read data out from the flash memory, reading the expected data from the first buffer, and calculating a failed bit number and a failed bit position from the expected data and the read data.

The expected data may include first expected data, and the methods may further include loading second expected data into the second buffer during reading of the second expected data from the first buffer.

The methods may further include loading a first pattern of expected data into the first buffer, and loading a second pattern of expected data into the second buffer. The first pattern of expected data may be different from the second pattern of expected data.

Reading read data out from the flash memory may include reading read data from a page of the flash memory into a page buffer, and reading the read data from the page buffer.

The expected data may be loaded into the first buffer prior to testing, and the read data may be read from the flash memory during testing.

The first buffer may include a plurality of memory segments, and loading expected data into the first buffer may include loading a plurality of different data patterns into the respective plurality of memory segments of the first buffer.

Calculating the failed bit number and the failed bit position may include comparing the read data and the expected data to generate a comparison result, and calculating the failed bit number based on the comparison result.

The methods may further include storing the failed bit number in a register, and providing a testing unit with the failed bit number in response to a request signal from the testing unit.

Calculating the failed bit position may include generating a read data parity value from the read data and an expected data parity value from the expected data, respectively, and calculating the failed bit position from the read data parity value and the expected data parity value.

The methods may further include storing the failed bit position in a register, and providing a testing unit with the failed bit number in response to a request signal from the testing unit.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a block diagram showing a memory system according to some embodiments of the present invention.

FIG. 2 is a block diagram showing a failed bit count unit as illustrated in FIG. 1 according to some embodiments of the invention.

FIG. 3 is a block diagram showing a failed bit position unit as illustrated in FIG. 1 according to some embodiments of the invention.

FIG. 4 shows exemplary parity generation for the fail-bit position generator of FIG. 3.

FIG. 5 is a flowchart illustrating bit line test operations according to some embodiments of the invention for a semiconductor memory device as illustrated in FIG. 1.

FIG. 6 shows a block diagram for a memory system according some embodiments of the present invention.

FIG. 7 shows an exemplary partitioning of the buffer memory and the memory pages into a plurality of testing patterns.

FIG. 8 shows another exemplary partitioning of the buffer memory and the memory pages into a plurality of testing patterns.

### DETAILED DESCRIPTION OF EMBODIMENTS OF THE INVENTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof. As used herein, the term “signal” may take the form of a continuous waveform and/or discrete value(s), such as digital value(s) in a memory or register.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the present invention are described below with reference to block diagrams, including operational flow charts, of semiconductor devices and associated methods according to various embodiments of the invention. It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved.

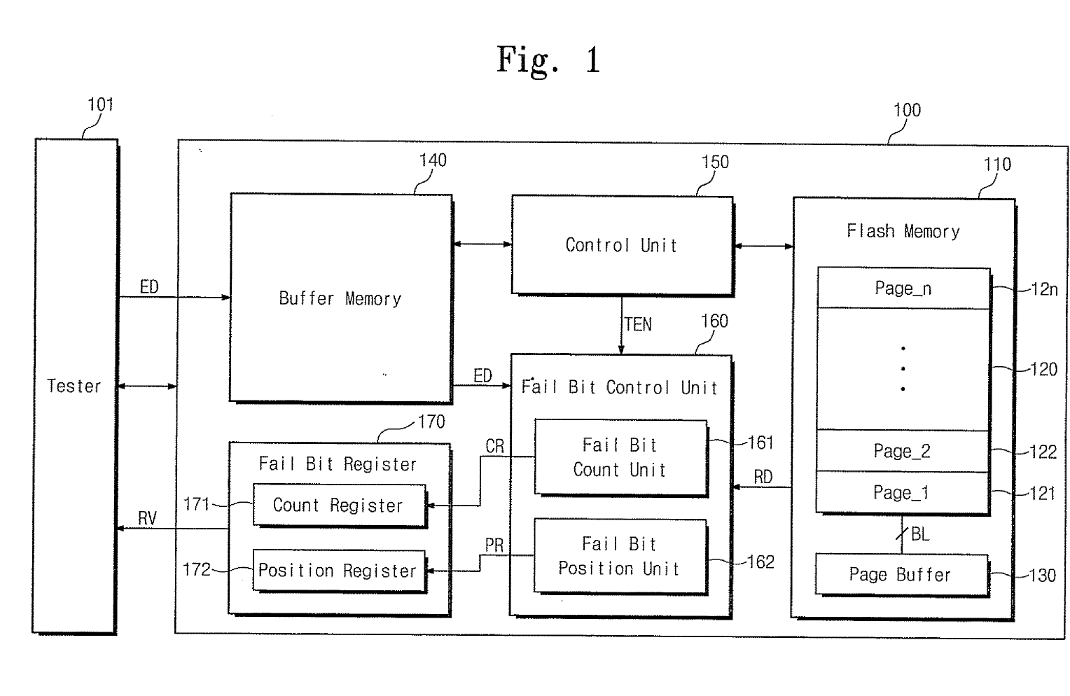

FIG. 1 is a block diagram showing a memory system according to some embodiments of the present invention. A semiconductor memory device 100 receives expected data ED from a tester 101 in a test operation. The semiconductor memory device 100 performs a failed bit test operation and provides the tester 101 with failed bit information based on the result of the test operation. The semiconductor memory device 100 includes a flash memory 110, a buffer memory 140, a control unit 150, a fail-bit control unit 160, and a failed bit register 170.

The flash memory 110 includes a cell array 120 and a page buffer 130. The cell array 120 includes a plurality of pages 121 to 12n. Each of the pages may be a basic unit for a read/write operation. That is, the flash memory 110 may perform read/write operations on a page by page basis. The cell array 120 is connected to the page buffer 130 through bit lines BL. The page buffer 130 stores data to be programmed in a page and/or data read out from a page.

The buffer memory 140 receives and stores expected data ED from the tester 101 in a test operation. The buffer memory 140 can be realized with a random access memory such as DRAM, SRAM, and the like. A conventional semiconductor memory device may not include a buffer memory for storing expected data. Accordingly, a conventional semiconductor memory device may be configured to receive expected data from a tester in predetermined units (e.g., byte or word units) in order to perform a failed bit test operation with respect to a page. Thus, a conventional configuration may require an excessive amount of time to perform a failed bit test operation.

A semiconductor memory device 100 according to embodiments of the present invention includes a buffer memory 140 that is configured to store the expected data ED. Afterwards, the buffer memory 140 may act as a tester that is embedded in the semiconductor memory device 100. Accordingly, the semiconductor memory device 100 can perform failed bit test operations in a reduced time compared to conventional semiconductor memory devices.

The control unit 150 is configured to control the overall operation of the semiconductor memory device 100. In a failed bit test operation, the control unit 150 receives a test command from the tester 101. The control unit 150 receives the expected data ED from the buffer memory 140 and programs the expected data ED in a page of the flash memory 110 (e.g., page 121) based on a program algorithm. Furthermore, the control unit 150 may supply the fail-bit control unit 160 with a test enable signal TEN in response to the test command.

The fail-bit control unit 160 performs a failed bit test operation in response to the test enable signal TEN. The fail-bit control unit 160 receives the expected data ED from the buffer memory 140 and receives the read data RD from the flash memory 110. That is, the read data RD is data read out from a page (e.g., page 121) of the flash memory 110 where the expected data ED is stored.

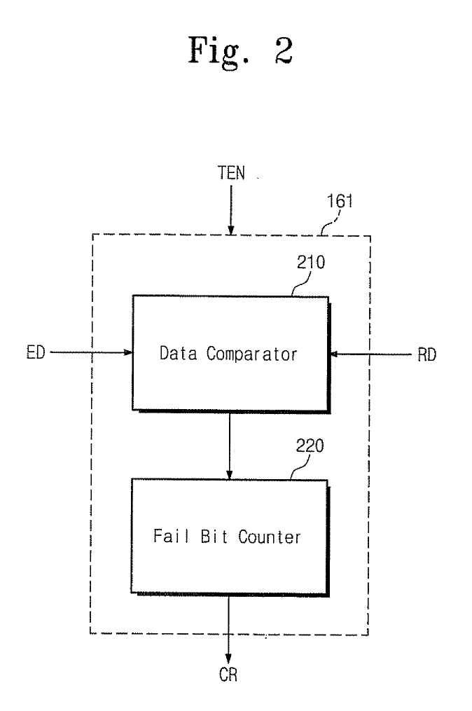

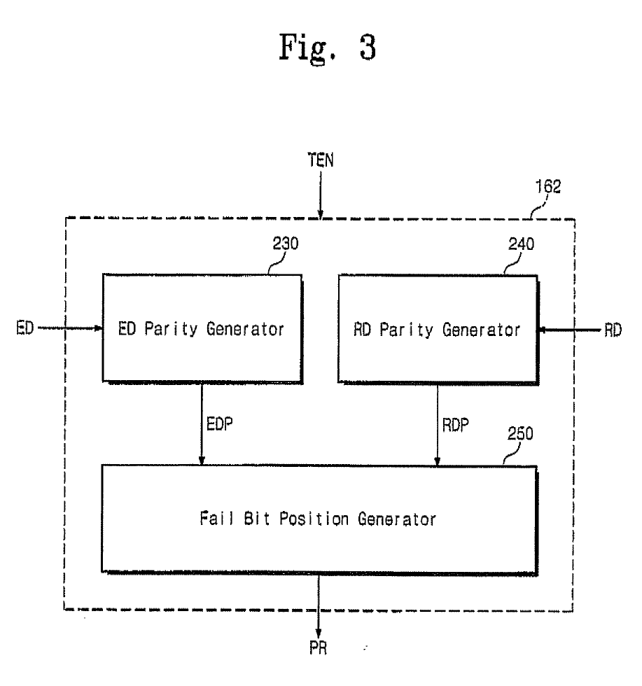

The fail-bit control unit 160 is configured to calculate the number of failed bits (i.e. the failed bit number) and the position of the failed bits (i.e. the failed bit positions) existing in the page 121 of the flash memory 110, based on a comparison of the expected data ED and the read data RD. Referring to FIG. 1, the fail-bit control unit 160 includes a failed bit count unit 161 and a failed bit position unit 162. The failed bit count unit 161 is configured to count the number of failed bits and to output a count result CR. The failed bit position unit 162 is configured to calculate the positions of the failed bits and output a position result PR. The failed bit count and position units 161 and 162 are illustrated in more detail in FIGS. 2 and 3.

Referring to FIG. 2, the failed bit count unit 161 operates responsive to the test enable signal TEN. The failed bit count unit 161 receives the expected data ED and the read data RD and responsively calculates a failed bit number. The failed bit count unit 161 includes a data comparator 210 and a failed bit counter 220.

The data comparator 210 receives the expected data ED and the read data RD in predetermined units (e.g., byte or word units) and compares the received data RD to the expected data ED. In the following discussion, a “word” refers to a 16-bit unit of data, and a “byte” refers to an 8-bit unit of data. Assuming that a page consists of 2K-bytes of data, a data comparator 210 configured as shown in FIG. 2 may receive 8-bit data 2K times and/or may receive 16-bit data 1K times in order to compare a page of expected data to a page of read data.

The failed bit counter 220 calculates a failed bit number from an output of the data comparator 210. The failed bit number refers to the number of different (i.e. mismatched) bits between the expected data ED and the read data RD. The failed bit counter 220 outputs the count result CR.

Referring to FIG. 3, the failed bit position unit 162 operates responsive to the test enable signal TEN. The failed bit position unit 162 receives the expected data ED and the read data RD and calculates a failed bit position. The failed bit position unit 162 includes an expected data parity generator 230, a read data parity generator 240, and a failed bit position generator 250.

The expected data parity generator 230 receives the expected data ED in predetermined units (e.g., word or byte units) and generates an expected data parity value EDP. The read data parity generator 240 receives the read data ED in predetermined units (e.g., word or byte units) and generates a read data parity value RDP. Assuming that a page consists of 2K-bytes of data, each of the expected and read data parity generators 230 and 240 receives 8-bit data 2K times and/or 16-bit data 1K times.

The failed bit position generator 250 receives the expected data parity value EDP and the read data parity value RDP and calculates positions of failed bits existing in the page 121. The failed bit position generator 250 outputs a position result PR of failed bits.

Returning to FIG. 1, the failed bit register 170 is configured to store the count result CR from the failed bit count unit 161 and the position result PR from the failed bit position unit 162. The failed bit register 170 outputs a register value RV in response to a request signal from the tester 101.

The failed bit register 170 includes a count register 171 and a position register 172. The count register 171 receives and stores the count result CR from the failed bit count unit 161, and the position register 172 receives and stores the position result PR from the failed bit position unit 162.

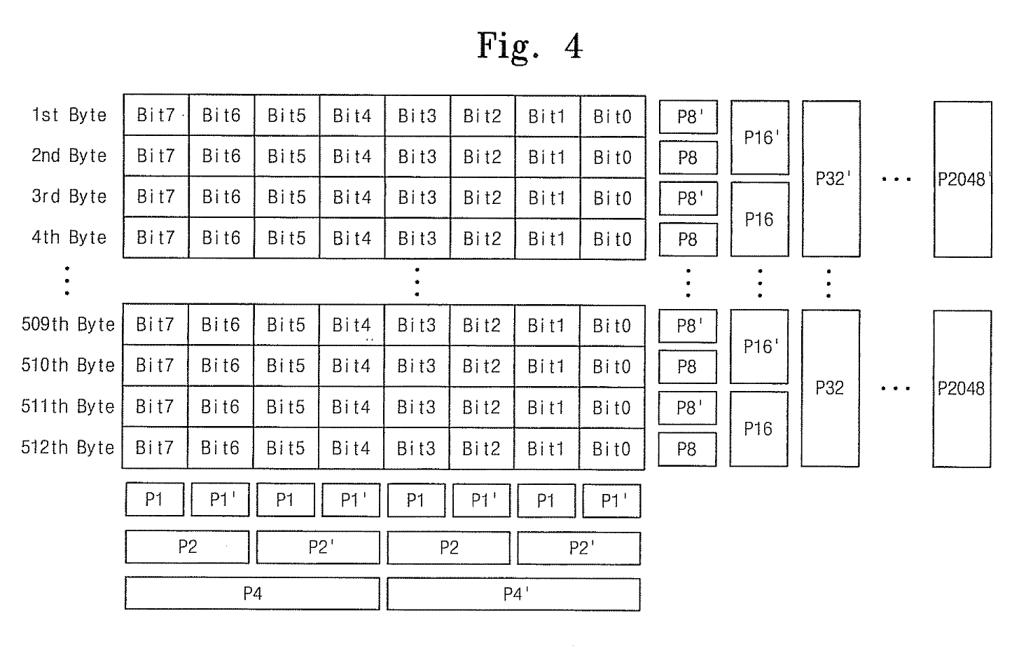

FIG. 4 shows exemplary parity generation for the fail-bit position generator 250 of FIG. 3. Referring to FIG. 4, the expected data ED received by parity generator 230 includes 512 bytes E1 to E512. The parity generator 230 generates column parity values P1, P2, P4, P1′, P2′ and P4′, and row parity values P8, P8′, P12, P12′, P32, P32′, . . . , P2048 and P2048′ for the expected data ED. Then, the parity generator 310 generates one or more parity codes to represent the set of parity values P1, P1′, P2, P2, P4, P4′ . . . P2048, and P2048′ corresponding to the expected data ED. For example, the parity generator 310 can generate a 24-bit parity code to represent the set of parity values P1, P1′, P2, P2′, P4, P4′ . . . P2048, and P2048′ corresponding to the expected data ED.

The column parity P1 is calculated by performing an exclusive-OR operation of Bit1, Bit3, Bit5 and Bit7 over all the bytes E1 to E512. The column parity P2 is calculated by performing an exclusive-OR operation of Bit2, Bit3, Bit6 and Bit7 over all the bytes E1 to E512. The column parity P4 is calculated by performing an exclusive or operation of Bit4, Bit5, Bit6, and Bit7 over all the bytes E1 to E512.

Similarly, the row parity P8 is calculated by exclusive-OR operation of all the bits in expected data E2, E4, . . . , E512. The row parity P16 is calculated by exclusive-OR operation of all the bits in reference E3, E4, E7, E8, . . . , E511, E512. The row parity P32 is calculated by exclusive-OR operation of all the bits in reference E5, E6, E7, E8, E13, E14, El5, E16 . . . , ES09, E510, E511, and E512. The remaining row parities are generated using a similar pattern. The parity generator 240 can generate a 24-bit parity code to represent the set of parity values P1, P2, P4,. P2048 corresponding to the read data RD.

The read data RD received by parity generator 240 may include 512 bytes D1 to D512. The parity generator 240 generates column parity values P1, P1′, P2, P2′, P4 and P4′, and row parity values P8, P8, P8′, P16, P16′, P32, P32′, . . . , P2048 and P2048′ for the read data RD. Then, the parity generator 240 generates one or more parity code to represent the set of parity values P8, P8, P8′, P16, P16′, P32, P32′ . . . , P2048 and P2048′ corresponding to the read data RD.

The position generator performs an exclusive-OR operation on the parity code EDP corresponding to the expected data and the parity code RDP corresponding to the read data. If all the bits in the exclusive-OR result are zero, then there is no fail-bit. If twelve of the bits are equal to 1, then there is one fail-bit, and the position of the error is indicated by a Hamming code, which is the bit pattern [P2048, P1024, P512, . . . P8, P4, P2, P1]. Specifically, part [P2048, P1024, P512, . . . P8] of the Hamming code specifies which byte has a fail-bit, and part [P4, P2, P1] of the Hamming code indicates which bit is the fail-bit. The failed bit position generator 250 outputs the fail-bit position as fail-bit position code PR.

In some embodiments of the present invention, the parity codes EDP and RDP may not be pre-stored but may be calculated at run-time, that is during a testing operation. Thus, fail-bit detection can be performed using any pattern inputted at testing time. Accordingly, there may be no need to use a fixed set of patterns for error detection.

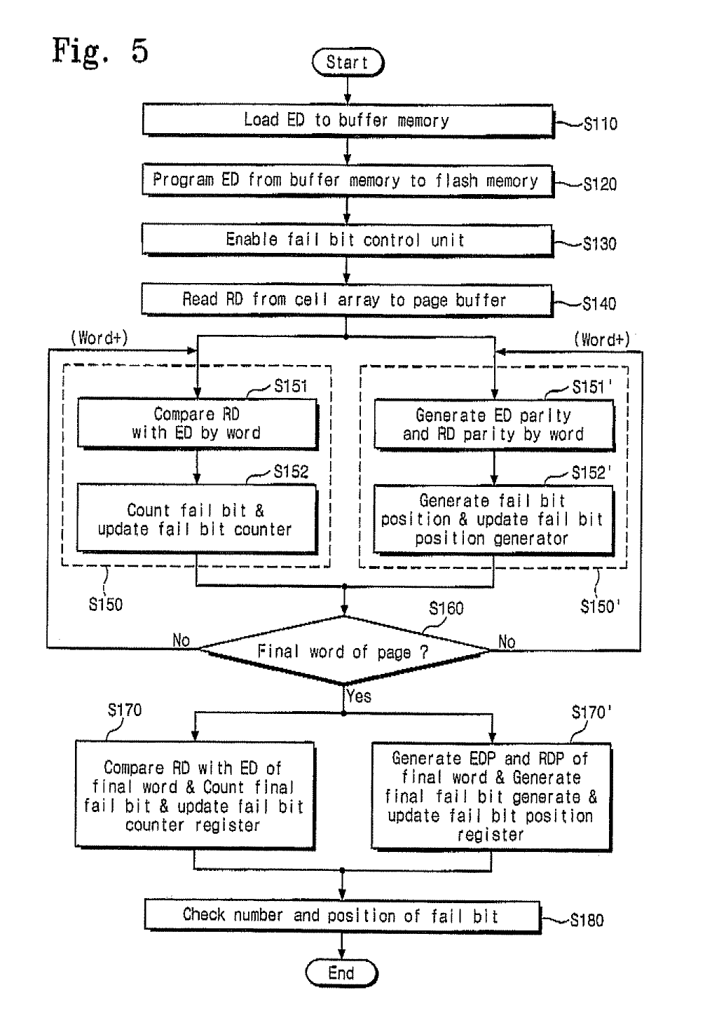

FIG. 5 is a flowchart illustrating failed bit test operations for a semiconductor memory device according to some embodiments of the present invention. A semiconductor memory device 100 according to some embodiments of the present invention may perform a failed bit test operation in response to a test command.

In step S110, the semiconductor memory device 100 stores the expected data ED in a buffer memory 140. The buffer memory 140 is configured to store a page of data transferred from a tester 101. In step S120, the expected data in the buffer memory 140 is programmed into a flash memory 110 under the control of a control unit 150. In step S130, the control unit 150 enables a fail-bit control unit 160. The fail-bit control unit 160 operates responsive to a test enable signal TEN. In step S140, a page buffer 130 of the flash memory 100 reads out data from a page 121 of a cell array 120 under the control of the control unit 150.

In steps S150 and S150′, the fail-bit control unit 160 calculates a failed bit number and a failed bit position from the page 121 of the cell array 120, in predetermined units (e.g., word units). The steps S150 and S150′ may be carried out simultaneously or non-simultaneously.

In step S150, the number of failed bits existing at the page 121 is calculated in word units. The step S150 includes steps S151 and S152. In step S151, a failed bit count unit 161 compares the expected data ED and the read data RD in word units. In step S152, the failed bit count unit 161 calculates a failed bit number according to a result of a comparison of the expected data ED and the read data RD in word units. The failed bit count unit 161 updates a failed bit counter 220 in word units.

In step S150′, positions of failed bits existing in the page 121 are calculated in word units. The step S150′ includes steps S151′ and S152′. In step S151′, a failed bit position unit 162 generates a read data parity value RDP and an expected data parity value EDP in word units. In step S152′, the failed bit position unit 162 calculates a failed bit position from the parity values RDP and EDP in word units. The failed bit position unit 12 updates a failed bit position generator 250 in word units.

In step S160, the fail-bit control unit 160 determines whether the received read data word is the last data word of the page 121. If the received read data word is not the last data word of the page 121, the steps S150 and S150′ may be repeated until the last data word is received. If the received read data is the last data word of the page 121, the procedure goes to steps S170 and S170′. The steps S170 and S170′ may be performed simultaneously or non-simultaneously.

In step S170, the fail-bit control unit 160 receives the last data word of the page 121 and calculates a final failed bit number. The operation of the step S170 is similar to that of step S150 with respect to the last data word. The failed bit count unit 161 updates a count register 171 of a failed bit register 170.

In step S170′, the fail-bit control unit 160 receives the last data word of the page 121 and calculates a final failed bit position. The operation of step S170′ is similar to that of step S150′ with respect to the last data word. The failed bit position count unit 162 updates a position register 172 of the failed bit register 170.

In step S180, the semiconductor memory device supplies the tester 101 with values (that is, failed bit number and position information) stored in the failed bit register 170 in response to a request signal from the tester 101. By using the above-described operations, the tester 101 may check the failed bit number and position in a page of the flash memory 110.

A semiconductor memory device according to some embodiments of the present invention can reduce testing time since an entire page of expected data may be provided to a buffer memory for testing at a time. A semiconductor memory device according to some embodiments of the present invention can quickly calculate useful information such as failed bit number information and/or failed bit position information through a fail-bit control unit and a failed bit register.

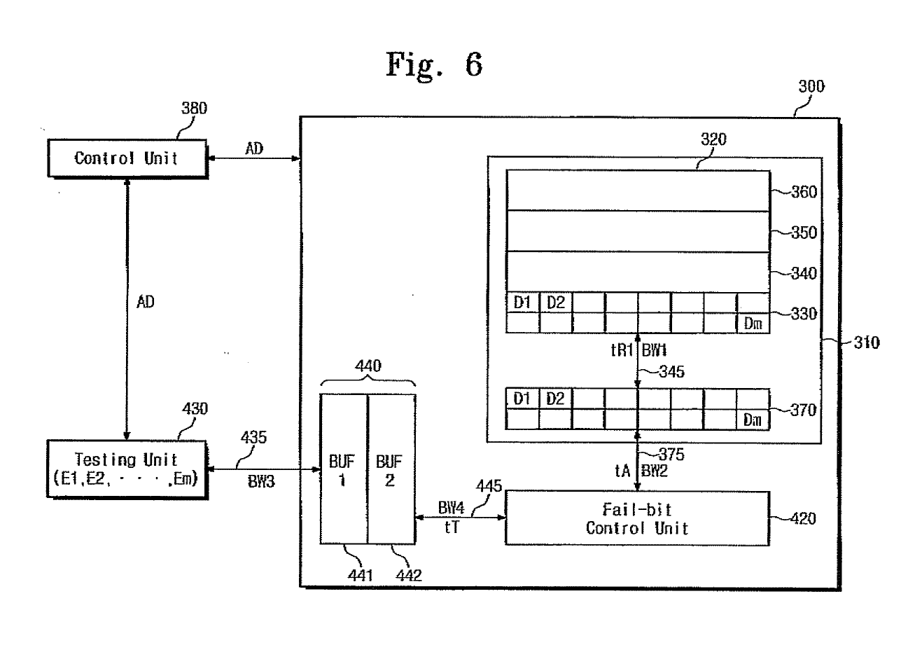

FIG. 6 shows a block diagram for a memory system according to further embodiments of the present invention. Referring to FIG. 6, the memory system includes a semiconductor memory device 300, a control unit 380, and testing unit 430. The semiconductor memory device 300 includes a flash memory 310, a buffer memory 440 and a fail-bit control unit 420. The fail-bit control unit 420 may have a similar configuration as the fail-bit control unit 160 shown in FIG. 1.

The flash memory 310 includes a data path 345 as an interface between the memory cell array 320 and the page buffer 370. The data path 345 has a width BW1, for example 16 bits. Thus, data can be transferred BW1 bits at a time between the memory cell array 320 and the page buffer 370. A data path 375 having a bit-width BW2 is provided as an interface between the page buffer 370 and the fail-bit control unit 420. A data path 435 having a bit-width BW3 is provided as an interface between the testing unit 430 and the buffer memory 440. Another data path 445 having a bit-width BW4 is provided as an interface between the buffer memory 440 and the fail-bit control unit 420.

During a programming operation, an externally provided input data is programmed into a target page 330 of the memory cell array 320. Each byte E1 to Em of the input data is stored into a corresponding byte D1 to Dm of the target page 330. Thus, the cells within each of the bytes D1-Dm in the target page 330 are programmed in accordance with corresponding bits in the input data E1 to Em.

Following the programming operation, in preparation for performing a testing operation to verify the success or failure of the programming of each of the cells affected by the programming operation, the testing unit 430 loads the expected data ED into one of BUF1 and BUF2 in the buffer memory 440. The expected data E1 to Em are loaded BW3 bits at a time into the BUF1 or BUF2 of the buffer memory 440 in accordance with the bit-width of the data path 435. Then, the testing unit 430 sends the testing request to the control unit 380 including addressing information specifying the memory sector, the memory page and/or the memory block to be verified.

In response to the testing request from the testing unit 430, the control unit 380 performs a read operation to read the stored/programmed data from the memory cell array 320 into the page buffer 370. During the read operation, the control unit 380 transmits the specified address information to the flash memory 310 to select the source memory page 330 to be read. Then, the data D1 to Dm stored/programmed in the cells of the source memory page 330 are transmitted BW1 bits at a time to the page buffer 370, in accordance with the bit-width BW1 of the data path 345. The reading operation is completed within a memory read time tR1, which is the time required for copying all of the data Dl to Dm from the memory cell array 320 to the page buffer 370. The memory page read time tR1 depends on the size of the memory page 330, the width BW1 of the data path 345, and a cell read time for accessing each cell and checking the status of the cell.

After all the data D1 to Dm from a target page 330 have been read into the page buffer 370, the control unit 380 transmits the test enable (TEN) signal to the fail-bit control unit 420 to initiate the testing operation on the read data. The fail-bit control unit 420 reads out the expected data E1 to Em BW4 bits at a time in accordance with the bit-width of the data path 445. The total transfer time of the expected data E1 to Em from the buffer memory 440 to the fail-bit control unit 420 is tT. The fail-bit control unit 420 reads out the read data D1 to Dm from the page buffer 370 BW2 bits at a time in accordance with the bit-width of the data path 375. The total transfer time of the read data D1 to Dm from the page buffer 370 to the fail-bit control unit 420 is tA. Then, the fail-bit control unit 420 compares each of the read data D1 to Dm to a corresponding one of the referenced data E1 to Em. The number of fail-bits is accumulated over the m-number of read data D1 to Dm.

The comparison operation may be performed by the fail-bit control unit 420 in a negligible amount of time in comparison with the time for reading into/from the different buffers. The data access time tA for the fail-bit control unit 420 to access the read data D1 to Dm in the page buffer 370 may also be negligible. The time for the testing unit 430 to transfer all of the expected data E1 to Em to BUF1 or BUF2 may not impact the testing time because the expected data E1 to Em may be loaded into the buffer memory 440 in advance of the testing operation. Thus, the total testing time for a memory page may be given by tR1+tT.

The dual buffering arrangement provided by BUF1 and BUF2 of the buffer memory 440 may increase the performance of the data transfer between the testing unit 430 and the fail-bit control unit 420. The fail-bit control unit 420 can read out data from reference BUF1 while the reference BUF2 is being loaded with additional expected data by the testing unit 430. Thus, the fail-bit control unit 420 may not have to wait for data to be transferred to one of the buffer memories BUF1 and BUF2 to perform testing of memory sectors, memory pages and/or memory blocks. Because data may be concurrently read out of buffer memory BUF1 by the fail-bit control unit 420 while new expected data is being loaded into reference BUF2, the read performance from the buffer memory 440 may be accelerated. Accordingly, the expected data loading time tT averaged over several pages may be smaller than the expected data loading time corresponding to a single page.

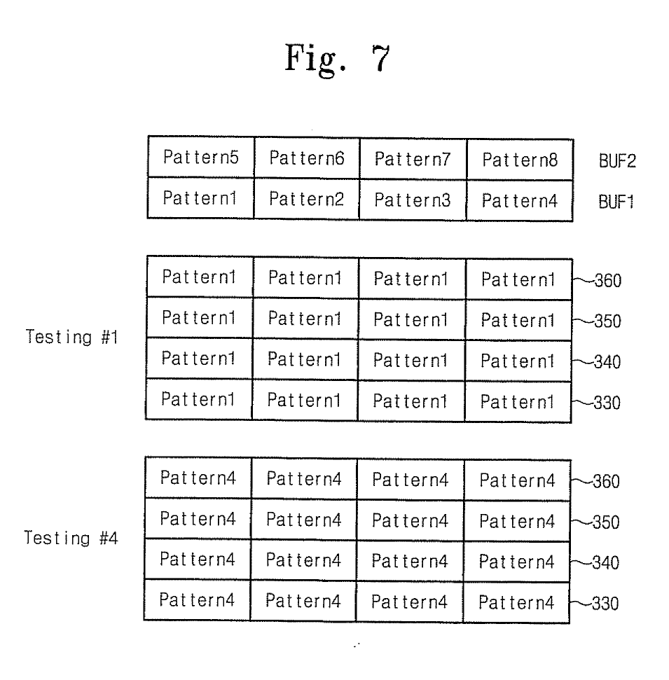

FIG. 7 shows an exemplary partitioning of the buffer memory 440 and the memory pages 330, 340, 350 and 360 into a plurality of testing patterns. Referring to FIG. 7, one or more of the buffers BUF1 and BUF2 can be partitioned into a plurality of sectors. A different reference pattern can be loaded into each sector. For example, Pattern1 to Pattern4 are loaded into first to fourth sectors of BUF1, respectively. In a first testing operation, Pattern1 is programmed into all of the sectors in memory pages 330, 340, 350 and 360. Then, the fail-bit control unit 420 compares each sector from each of the memory pages 330, 340, 350 and 360 to the reference Pattern1 to detect errors associated with reference Pattern1. The steps of programming and testing are repeated for each of the remaining three reference patterns Pattern2 to Pattern4. For example, in the fourth testing operation, Pattern4 is programmed into all of the sectors in memory pages 330, 340, 350 and 360. Then, the fail-bit control unit 420 compares each sector from each of the memory pages 330, 340, 350 and 360 to the reference Pattern4 to detect errors associated with reference Pattern4.

Moreover, while the fail-bit control unit 420 reads out data from the buffer BUF1, additional patterns can be loaded into the buffer BUF2. As shown in FIG. 7, Pattern5 and Pattern6 are already loaded into the buffer BUF2. More patterns, for example, Pattern7 and Pattern8 can be loaded for future testing by the test-bit control unit 420.

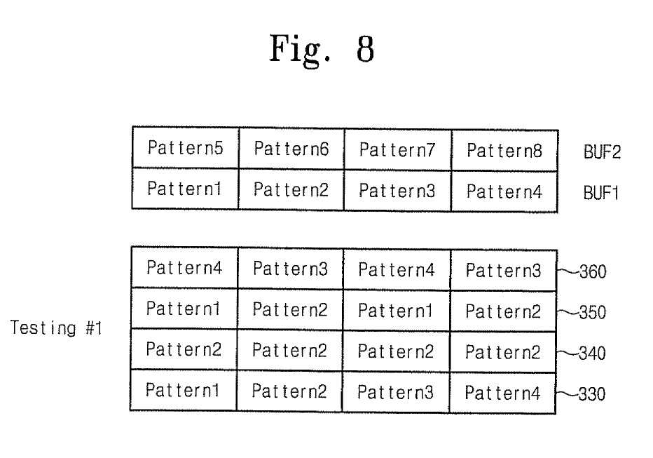

FIG. 8 shows another exemplary partitioning of the buffer memory and the memory pages into a plurality of testing patterns. Referring to FIG. 8, one or more of the buffers BUF1 and BUF2 can be partitioned into a plurality of sectors. A different reference pattern can be loaded into each sector. For example, Pattern1 to Pattern4 are loaded into first to fourth sectors of BUF1, respectively. During the programming operation, the patterns can be selectively stored into various sectors in the memory pages 330, 340, 350 and 360. For example, all four patterns Pattern1 to Pattern4 are stored in the respective sectors in memory page 330. Pattern 2 is loaded in all four sectors of memory page 340. Pattern1 and Pattern2 are alternately stored in the four sectors of memory page 350. Similarly, Pattern4 and Pattern3 are alternately stored in the four sectors of memory page 360. During the testing operation, the fail-bit control unit 420 compares each sector from each of the memory pages 330, 340, 350 and 360 to the one of the reference patterns Pattern1 to Pattern4 that was programmed into the sector.

In accordance with some embodiments of the present invention, a plurality of buffers may be provided for loading the expected data before performing a testing operation. The fail-bit control unit can access the expected data from one of the buffers while additional expected data are loaded into another buffer. Accordingly, the expected data loading time averaged over several pages is reduced.

In accordance with some embodiments of the present invention, the expected data is loaded in a data buffer before performing a testing operation and the read data is loaded in the data buffer during testing. Thus, the fail-bit control unit can access the expected data as soon as the read data is available in the data buffer. Thus, the fail-bit control unit may not have to wait for the expected data to be inputted. Accordingly, the testing performance may be improved.

It will be apparent to those skilled in the art that various modifications and variations can be made in the memory device and fail-bit test method thereof of the present invention without departing from the spirit or scope of the invention. Thus, it is intended that the present invention cover the modifications and variations of this invention provided they come within the scope of the appended claims and their equivalents.

What is claimed is:

1. A semiconductor memory device comprising:
a flash memory comprising a plurality of M-byte memory pages;
a buffer memory configured to receive expected data used to test for failed bits in the flash memory, wherein the buffer memory comprises a first M-byte buffer and a second M-byte buffer; and
a fail-bit control unit configured to receive the expected data from the buffer memory, configured to receive the read data from the flash memory, and configured to calculate a failed bit number and a failed bit position in response to a mis-match between the expected data and the read data.

2. The semiconductor memory device of claim 1, further comprising an M-byte page buffer configured to receive read data from the flash memory, wherein the fail-bit control unit is configured to receive read data from the page buffer.

3. The semiconductor memory device of claim 1, wherein the expected data corresponds to a page of the flash memory, and wherein the buffer memory is further configured to receive the expected data in a single programming operation.

4. The semiconductor memory device of claim 1, wherein the buffer memory is configured to store expected data in the first buffer while the fail-bit control unit reads expected data from the second buffer.

5. The semiconductor memory device of claim 1, wherein the fail-bit control unit comprises:
a failed bit count unit configured to calculate the failed bit number in response to the expected data and the read data; and
a failed bit position unit configured to calculate the failed bit position in response to the expected data and the read data.

6. The semiconductor memory device of claim 5, wherein the failed bit count unit comprises:
a data comparator configured to compare the expected data with the read data; and
a failed bit counter configured to calculate the failed bit number from a comparison result of the data comparator.

7. The semiconductor memory device of claim 5, wherein the failed bit position unit comprises:
an expected data parity generator configured to generate an expected data parity value from the expected data;
a read data parity generator configured to generate a read data parity value from the read data; and
a failed bit position generator configured to calculate the failed bit position from the expected data parity value and the read data parity value.

8. The semiconductor memory device of claim 1, further comprising a failed bit register configured to store the failed bit number and the failed bit position.

9. A memory system, comprising:
a semiconductor memory device comprising:
a flash memory comprising a plurality of M-byte memory pages;
a buffer memory configured to receive expected data used to test for failed bits in the flash memory, wherein the buffer memory comprises a first M-byte buffer and a second M-byte buffer; and
a fail-bit control unit configured to receive the expected data from the buffer memory, configured to receive the read data from the flash memory, and configured to calculate a failed bit number and a failed bit position in response to the expected data and the read data;
a control unit configured to control a testing operation of the semiconductor memory device; and
a testing unit configured to store expected data in the buffer memory and configured to notify the control unit of a memory page of the flash memory to be tested.

10. The memory system of claim 9, wherein the testing unit is configured to store first expected data in the first buffer, and to store second expected data in the second buffer while the fail-bit control unit reads the first expected data from the first buffer.

11. A method of testing for failed bits in a semiconductor memory device including a flash memory and a buffer memory including first and second buffers, the method comprising:
loading expected data into the first buffer;
programming the expected data into the flash memory;
reading read data out from the flash memory;
reading the expected data from the first buffer; and
calculating a failed bit number and a failed bit position from the expected data and the read data.

12. The method of claim 11, wherein the expected data comprises first expected data, the method further comprising loading second expected data into the second buffer during reading of the second expected data from the first buffer.

13. The method of claim 12, further comprising loading a first pattern of expected data into the first buffer, and loading a second pattern of expected data into the second buffer, wherein the first pattern of expected data is different from the second pattern of expected data.

14. the method of claim 11, wherein reading read data out from the flash memory comprises reading read data from a page of the flash memory into a page buffer, and reading the read data from the page buffer.

15. The method of claim 11, wherein the expected data is loaded into the first buffer prior to testing, and the read data is read from the flash memory during testing.

16. The method of claim 11, wherein the first buffer comprises a plurality of memory segments, and wherein loading expected data into the first buffer comprises loading a plurality of different data patterns into the respective plurality of memory segments of the first buffer.

17. The method of claim 11, wherein calculating the failed bit number and the failed bit position comprises:
comparing the read data and the expected data to generate a comparison result; and
calculating the failed bit number based on the comparison result.

18. The method of claim 17, further comprising:
storing the failed bit number in a register; and
providing a testing unit with the failed bit number in response to a request signal from the testing unit.

19. The method of claim 11, wherein calculating the failed bit position comprises:
generating a read data parity value from the read data and an expected data parity value from the expected data, respectively; and
calculating the failed bit position from the read data parity value and the expected data parity value.

20. The method of claim 19, further comprising:
storing the failed bit position in a register; and
providing a testing unit with the failed bit number in response to a request signal from the testing unit.
